(19) United States
(12) Patent Application Publication
(10) Pub. No.: US 2009/0241011 A1
(43) Pub. Date: Sep. 24, 2009

(54) MEMORY DEVICE

(75) Inventor: Michio Yamamoto, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/349,067

(22) Filed: Jan. 6, 2009

(30) Foreign Application Priority Data
Mar. 18, 2008 (JP) 2008-069855

(51) Int. Cl. G11C 29/04; G06F 11/22

(52) U.S. Cl. 714/769; 714/E11.145

(57) ABSTRACT

A method of controlling a memory device connectable to a host for sending out a command to the memory device, having a medium including a plurality of sectors, a head for writing data into and reading data from the medium, and a buffer memory for storing information, the method has receiving information indicating an error of data read out from a sector by the memory device and storing identification information of the sector where the error has been detected in the buffer memory and receiving information indicating an error of data read out from a sector by the host and storing in the buffer memory identification information of the sector where the error has been detected such that in the absence of vacant area in the buffer memory, the identification information is written over into an address where information of sector error detected by the memory device has been stored.

### BACKGROUND

The present art relates to a technology that manages logs relating to errors detected in data reading from a recording medium such as a memory device.

One of methods for designating a position to store data may use an LBA (Logical Block Address) in order to perform data reading/writing processing on a recording medium such as a memory device. In accordance with the method, correspondence is established between the address designated by an LBA and a sector of a recording medium on the one-to-one basis, and the sector can be uniquely identified by the corresponding LBA. An LBA may be assigned to a sector freely in a magnetic disk apparatus.

In a case where a sector (which will be called bad sector) exists from/to which data cannot be read/written due to a fault of a recording medium, for example, a magnetic disk apparatus can perform recovery processing such as rewriting or verification on the bad sector and reassignment of an assigned LBA to a different spare sector.

Here, the replacement processing by a spare sector may include replacement processing in response to a explicit request for implementing the reassignment, that is, replacement processing based on a command from a host and automatic replacement processing by implementing the reassignment autonomously in a magnetic disk apparatus.

As described above, in a magnetic disk apparatus, with the implementation of the automatic replacement processing, information on a read error, for example, is recorded as an error log on a memory within the magnetic disk apparatus. Then, the error log is referred to determine whether the bad sector is accessed or not.

### SUMMARY

According to an aspect of an embodiment, a method of controlling a memory device connectable to a host for sending out a command to the memory device, the memory device having a medium capable of storing data and including a plurality of sectors, a head for writing data into and reading data from the medium, and a buffer memory for storing information, the method has receiving information indicating an error of data read out from a sector by the memory device and storing identification information of the sector where the error has been detected in the buffer memory and receiving information indicating an error of data read out from a sector by the host and storing in the buffer memory identification information of the sector where the error has been detected such that in the absence of vacant area in the buffer memory, the identification information is written over into an address where information of sector error detected by the memory device has been stored.

### BRIEF DESCRIPTION OF THE DRAWINGS

FIG. 1 is a configuration diagram of a magnetic disk apparatus;

FIG. 2 is a principle diagram for explaining an error log management method according to an embodiment of the present invention;

FIGS. 3A and 3B are diagrams for explaining the error log management method according to the embodiment; and

FIGS. 4A and 4B are flowcharts illustrating processing of registering an error log in an error logging area.

### DESCRIPTION OF THE PREFERRED EMBODIMENTS

A method will be further described for detecting a bad sector by performing read processing in accordance with a read command from a host. First of all, if a read command is issued from a host to a magnetic disk apparatus, the sector position corresponding to the range of an LBA requested by the read command is obtained in the magnetic disk apparatus having received the read command. Read processing is started on the obtained sector position.

If any bad sector is detected in the read processing and if the sector data cannot be read, an error on the read command based on the fact is notified to the host. With this, the position of the bad sector is recorded at an error log. The error log is placed on a memory within the magnetic disk apparatus.

After that, if a write command is issued from the host to the magnetic disk apparatus, whether the detected bad sector is included in the range of the LBA requested by the write command or not is checked. If the bad sector is included in the range of the LBA designated by the write command, the magnetic disk apparatus autonomously performs the recovery processing on the bad sector.

Here, a predetermined area is assigned on an memory of the magnetic disk apparatus as an error logging area that stores an error log recording an error detected in data reading from a recording medium. Therefore, the limited number of logs can be registered.

Hitherto, recovery processing is performed on a bad sector position registered in the error logging area, and the recording area is secured by deleting the information recorded in the error logging area if the fact that the sector at the error sector position has been recovered to a normal state is confirmed. If all of the error logging areas are used without performing recovery processing, the error log to be registered next is overwritten on the area storing the oldest log.

If a bad sector is detected in read processing in response to a read command received from a host, rewrite processing is performed on the sector position. Therefore, recovery processing (or automatic replacement) is performed on the bad sector detected by the read command immediately after the detection.

On the other hand, as described above, the magnetic disk apparatus automatically examines the bad sector if the own apparatus awaits a command. A BMS (Background Media Scan) function refers to the function for checking the user data written state by a magnetic disk apparatus itself.

If the BMS function detects a bad sector, retry processing is performed which repeats rereading. Then, if the read processing normally completes with the retry processing, recovery processing such as rewriting and verification is performed. If the read processing does not complete normally even by performing the retry processing, the position (or LBA) of the bad sector is logged as an error position. After that, if a write command is received from the host for the bad sector detected by the BMS function, the recovery processing is performed by following the steps as described above.

The bad sectors detected by the BMS are due to the read processing started by a magnetic disk apparatus itself. Therefore, the recovery processing is not performed in accordance with an instruction from the host side on a detected bad sector, like the bad sectors detected by the read commands from the host. In other words, the recovery processing is performed if an instruction to write to the position of the bad sector is received from the host. The range of the sectors on which the BMS is performed includes an unused sector on which valid data is not written. If an error is detected by the BMS on the unused sector and is logged in an error logging area, write processing on the sector position may not be performed.

For those reasons, the recovery processing is not performed validly on information registered in an error logging area, which increases the possibility of the overflow of logs from the error logging area as a result.

Furthermore, if the error logging area is full and another bad sector is detected after that, older logs are overwritten in order. The error position with the log deleted by the overwriting is left without the recovery processing thereon, which reduces the frequency of the implementation of the recovery processing on sectors recording valid data as a result.

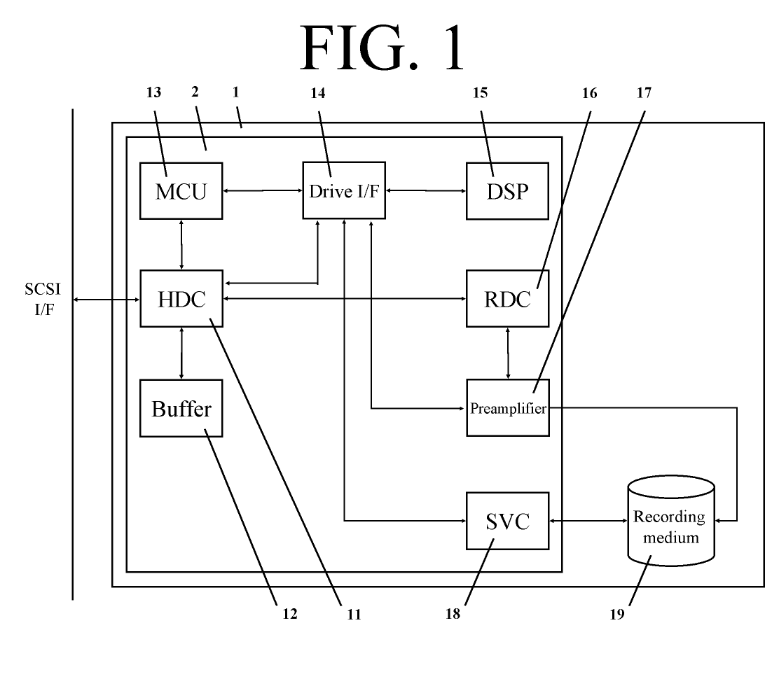

With reference to drawings, preferred embodiments of the present invention will be described in detail below. FIG. 1 is a configuration diagram of a magnetic disk apparatus. A magnetic disk apparatus 1 shown in FIG. 1 mainly includes a control portion 2 and a recording medium 19, and the control portion 2 includes a hard disk controller (HDC) 11, a buffer 12, a microcontroller (MCU) 13, a drive interface (drive I/F) 14, a digital signal processor (DSP) 15, a read channel (RDC) 16, a preamplifier 17 and a servo controller (SVC) 18.

The recording medium 19 records data sent from a host. The recording medium 19 is capable of storing data and includes a plurality of sectors. The HDC 11 receives a command and/or data from the host through an SCSI interface (or Small Computer System Interface). The buffer 12 functions as a cache memory and saves the write data received from the host. In data reading, the data read out from the recording medium 19 is saved in the buffer 12 and then is transferred to the host.

The MCU 13 controls the components and, in relation to the management of error logs, creates an error log including information such as an LBA if the fact that a bad sector has been detected by read processing. The created error log is stored in an error logging area prepared in a predetermined area on a memory. The drive I/F 14 is a communication interface with the recording medium 19.

The DSP 15 performs processing on a digital signal. The preamplifier 17 amplifies the signal read out from the recording medium 19 and supplies the result to the read channel 16. The read channel converts the input signal from the preamplifier 17 to a digital signal.

A memory device is connectable to a host for sending out a command to the memory device. The memory device has a head for writing data into and reading data from the recording medium 19 and a buffer memory for storing information.

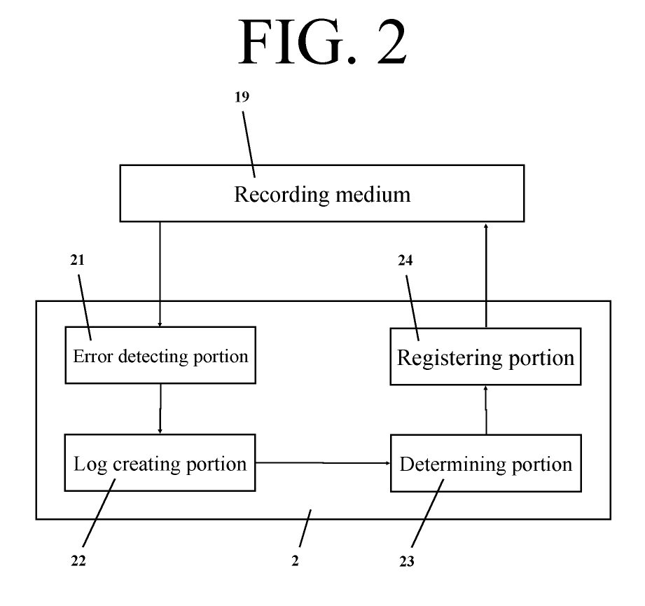

With reference to FIGS. 2 to 4, a method for managing error logs in the magnetic disk apparatus 1 according to this embodiment will be described more specifically below. FIG. 2 is a principle diagram for explaining the error log management method according to this embodiment. In the control portion 2, the components relating to the management of error logs is shown as functional blocks and include an error detecting portion 21, a log creating portion 22, a determining portion 23 and a registering portion 24.

The error detecting portion 21 detects an error in a sector of the recording medium 19. The error detection may be by a read command from a host or by the BMS function in the magnetic disk apparatus 1.

The log creating portion 22 gives information describing an error detecting method and a registration number to the LBA indicating the position of a bad sector detected by the error detecting portion 21 if any. The determining portion 23 determines whether the log for a newly detected error is to be registered or not by comparing the sector position of the newly detected bad sector and the information supplied given by the log creating portion 22 and the sector position already registered in an error logging area and information given thereto.

The registering portion 24 registers a log in an error logging area in accordance with the determination result by the determining portion 23. In this way, in the error log management method according to this embodiment, if an error is detected upon readout from the recording medium 19, the information on the sector having the detected error, which is handled as a bad sector, is registered in an error logging area. In this case, the information is given to the LBA indicating the sector position where the error has been detected and is registered as an error log along with the LBA. In order to register one error log newly, whether the error log is to be registered by priority or not is determined with reference to the already registered error logs and added information as required, and registration processing is performed on the information determined to register.

The control portion 2 receives information indicating an error of data read out from a sector by the memory device and stores identification information of the sector where the error has been detected in a memory and receives information indicating an error of data read out from a sector by the host and stores in the buffer memory identification information of the sector where the error has been detected such that in the absence of vacant area in the buffer memory, the identification information is written over into an address where information of sector error detected by the memory device has been stored.

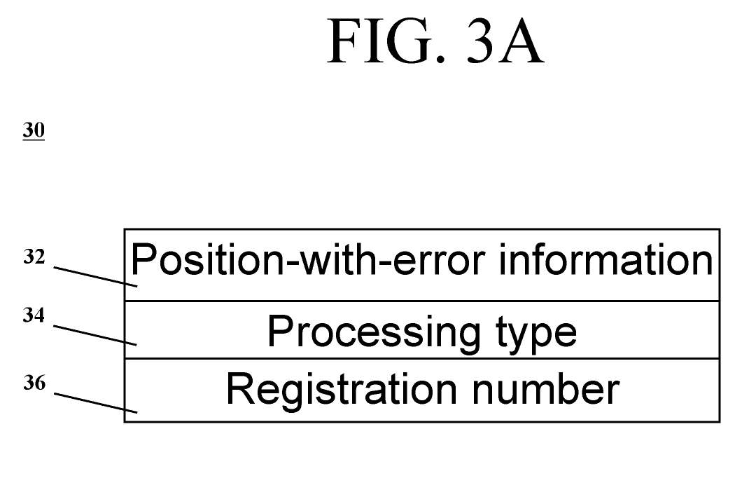

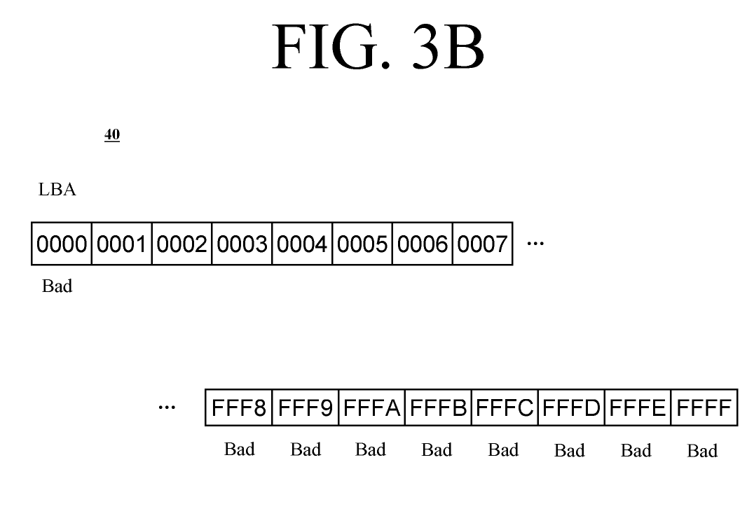

FIGS. 3A and 3B are diagrams for explaining the error log management method according to this embodiment. FIG. 3A is a data configuration diagram of one error log, and FIG. 3B is a diagram showing an error log registered in the error logging area.

As shown in FIG. 3A, one error log includes 30 position-with-error information 32, a processing type 34 and a registration number 36. The position-with-error information is information indicating the sector position where an error has been detected and, more specifically, is the LBA to be assigned to a sector of the recording medium 19. The processing type indicates the type of the processing in which an error is detected and, more specifically, is to be stored as a value indicating either read command from a host or BMS function in the magnetic disk apparatus 1. The registration number is a value to be stored indicating the order of registration of error logs in an error logging area.

As shown in FIG. 3B, the information indicating the position of a bad sector detected by the read command from a host or the BMS function in the magnetic disk apparatus 1 is stored in an error logging area along with the processing type and the registration number.

Now, a case will be described where, in a configuration including a total of 17 sectors of “0x0000 and 0xFFF0 to 0xFFFF” as LBAs of bad sectors and allowing registration of 16 (0x10) logs to be registered in an error logging area, processing is performed by the following steps.

First of all, the implementation of the read command is started for the sectors under the LBAs in the range of 0x0000 to 0xFFFF by means of the BMS function. While read processing is being performed on the sectors by the BMS, the read commands for the range of LBAs 0x0000 to 0x0010 are received from the host side. The magnetic disk apparatus 1 performs the read processing in response to an instruction from the host in priority to the read processing by the BMS.

An error at the LBA “0x0000” of the detected bad sector is registered in the error logging area if the read processing by the BMS function is performed on the range of LBAs 0x0000 to 0x1000 until the BMS is aborted by the issuance of a read command from the host.

If the implementation of the read command is started in response to the instruction from the host, the read processing by the BMS is aborted, and an error is detected in the sector at the LBA “0x0000”. Comparing the log for the detected error and the already registered error log, the LBA is the same but the processing types are different. In this case, the log storing the value representing the read command from the host as the processing type is prioritized. In other words, the newly created log is overwritten.

After that, if the read processing in response to the read command from the host completes, the read processing by the BMS is restarted. Then, if the BMS detects errors in the sectors at the LBAs 0xFFF0 to 0xFFFF, the error logs are created for the sectors and are registered in the error logging area.

Though 16 bad sectors are newly detected by the BMS, one log has already been registered. The processing type for the registered log indicates “Read Command from Host”. Therefore, the already registered log is prioritized, and 15 logs, which can be registered in the error logging area, are only registered among the newly created logs.

In this way, an error detected by the read processing in response to the command from the host is logged in priority to an error detected by the BMS function in the magnetic disk apparatus 1. This can increase the number of opportunities of implementation of recovery processing in managing the error logs in limited areas. The replacement processing on a bad sector with a spare sector based on the implementation of recovery processing deletes the error log for the bad sector. Therefore, the error logging area can be used effectively.

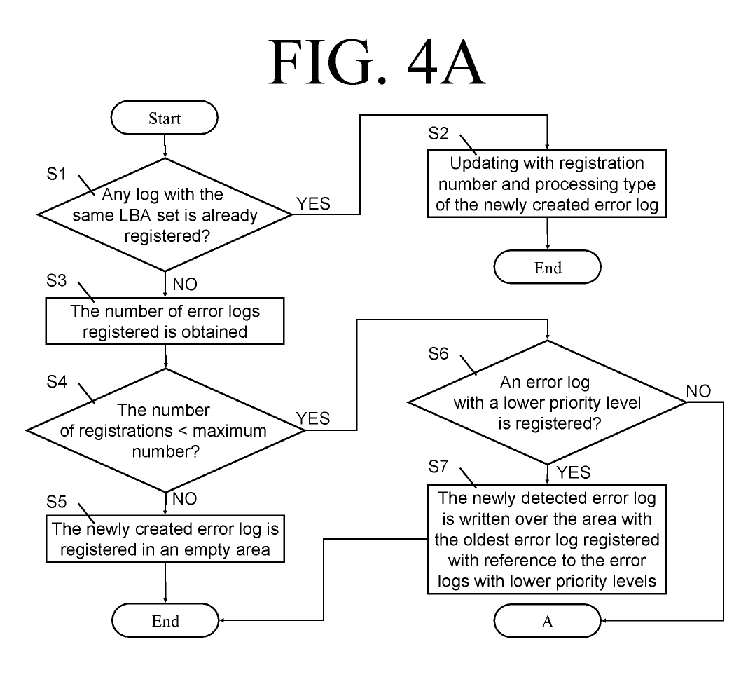

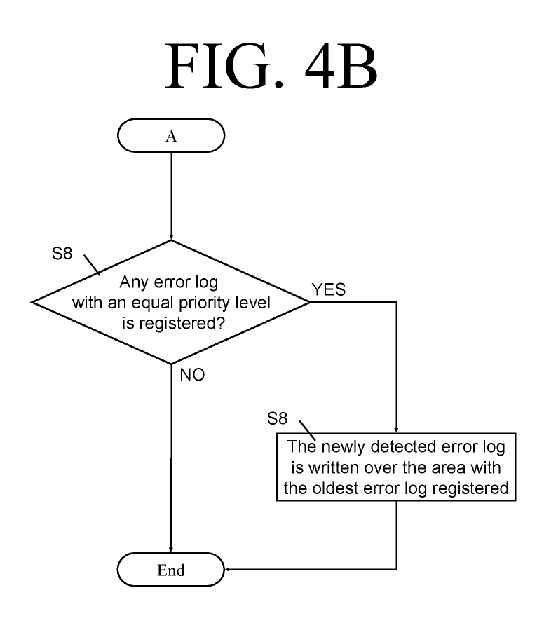

FIGS. 4A and 4B are flowcharts illustrating processing of registering an error log in an error logging area. The processing illustrated in FIGS. 4A and 4B is performed every time an error is detected in a certain sector and an error log is created for the error.

First of all, in step S1, a log in a sector in which an error is newly detected and a log already registered in an error logging area among logs are compared in position-with-error information, that is, the LBAs. Whether any log with the same LBA set is already registered or not is determined on the basis of the comparison. If it is determined that an error log with the same LBA is registered, the processing moves to step S2. In step S2, the registration number and processing type in the already registered error log with the same LBA are updated with the registration number and processing type of the newly created error log. Then, the processing ends.

If step S1 results in the determination that the log with the same LBA is not registered, the processing moves to step S3 where the number of error logs registered in the error logging area (or number of registrations) is obtained. Then, in step S4, whether the number of registrations is equal to the maximum number of possible registrations or not is determined.

If step S4 results in the determination that the number of registrations is lower than the maximum number of possible registrations, the processing moves to step S5 where the newly created error log is registered in an empty area, and the processing ends. If step S4 results in the determination that the number of registrations is equal to the maximum number of possible registrations, the processing moves to step S6 where the error log for the newly detected bad sector and the registered error logs are compared to determine whether any error log has a lower priority level among the registered error logs.

Here, an error log with a lower priority level is determined with reference to the processing types in the error logs. As described above, in this embodiment, either read command from the host or BMS function is set as a processing type, and an error log with the BMS function set is determined as an error log with a lower priority level.

If step S6 results in the determination that an error log with a lower priority level is registered, the processing moves to step S7. In step S7, the error log for the newly detected error is written over the area with the oldest error log registered with reference to the error logs with lower priority levels, more specifically, the registration numbers of the error logs with the BMS function set as the processing type. Then, the processing ends.

If step S6 results in the determination that no error logs with lower priority levels are registered, the processing moves to step S8. Then, whether any error log with an equal priority level is registered or not is further determined.

If step S8 results in the determination that an error log with the equal priority level is registered, the processing moves to step S9 where the error log for the newly detected error is written over the area with the oldest error log registered with reference to the registration numbers of error logs registered in the error logging area. Then, the processing ends.

If step S8 results in the determination that no error logs with the equal priority level are registered, no particular processes are performed, and the processing ends.

As described above, in the error log management method according to this embodiment, if a maximum number of error logs are registered in the error logging area and if there are error logs with lower priority levels than that of the error log for a newly detected error, the error log for the newly detected error is overwritten in the area storing the oldest error log among them. If no error logs with lower priority levels are registered in the error logging area, the error log for the newly detected error is overwritten in the area storing the oldest error log among the error logs with the equal priority level.

The priority level is determined on the basis of the processing type of the read processing in which an error is detected indicating the read command from a host or the BMS function of the magnetic disk apparatus 1. Then, the error detected by the read processing performed by the read command from the host is registered in the error logging area by priority. This may contribute to the secure implementation of recover processing on the bad sector. Because the log having undergone recovery processing can be deleted, the more secure implementation of recovery processing can effectively prevent the overflow of error logs from the error logging area.

If the read processing based on the read command from the host and the read processing by the BMS function in the magnetic disk apparatus 1 detect an error in a same sector, the error log created for the error detected in response to the read command from the host is registered by priority. For a case where an error is detected by both of the read command from the host and BMS function in a same sector, the value representing the read command from the host may be preset as the processing type. Thus, if the number of registered logs in the error logging area is at maximum, the log for the error detected by the read command from the host has a higher priority level than that of the log for the error detected by the BMS function and is therefore protected from overwriting. This may contribute to the more secure implementation of recovery processing. The more secure implementation of recovery processing can effectively prevent the overflow of logs from the error logging area.

In order to solve the problems above, according to an aspect of the present invention, there is provided a recording apparatus including a recording medium, storage means for storing positional information of a bad sector of the recording medium as a log, detecting means for detecting a bad sector by reading out data sequentially from sectors of the recording medium, log creating means for, if a bad sector is detected by the detecting means, creating the priority level for logging, which is determined in accordance with sector identification information for identifying the bad sector and the method for detecting a bad sector in the detecting means, as a log to be registered, determining means for determining whether the log on the newly detected bad sector is to be registered or not on the basis of the comparison between the sector identification information and priority level of the log stored in the storage means and the sector identification information and priority level created by the log creating means, and registering means for registering the log determined to be registered by the determining means along with the sector identification information and priority level in the storage means.

In the recording apparatus, if a bad sector is newly detected, the sector identification information and the priority level are given in an error log for the bad sector. Whether the log newly detected by the storage means is to be registered or not may be determined on the basis of the comparison in priority level between already registered logs and the newly created log. A log with a high degree of importance may be registered by priority.

The priority level may be set higher if the processing of detecting a bad sector by the detecting means is implemented in response to a request from a host computer, and the determining means may determine that the log on the newly detected bad sector is to be registered if the priority level in the log for the bad sector newly detected by the detecting means is higher than the priority levels of the logs stored in the storage means.

The configuration allows the log by the detecting processing implemented in response to a write request, for example, from the host computer to be registered by priority compared with the log by detecting processing autonomously performed by the recording apparatus. Thus, the error log detected by the detecting processing implemented in response to a write request from the host computer is recorded by priority, which may improve the frequency of implementation of recovery.

The determining means may determine whether the log for the newly detected bad sector is to be registered or not if the number of logs stored in the storage means is at maximum, and the registering means may register the log in the storage means if the determining means determines that the log for the newly detected bad sector is to be registered and if the number of logs stored in the storage means is under a maximum value.

Alternatively, the determining means may determine the log for the newly detected bad sector is to be registered if the logs stored in the storage means include a log with the sector identification information mutually matched with the sector identification information of the newly detected bad sector.

The log creating means may further create a registration number indicating the order of registration of the log and, if the number of logs stored in the storage means is at maximum, the registering means may write over the oldest log of the logs stored in the storage means with reference to the registration numbers.

The disclosed recording apparatus allows the registration of an error log with a high degree of importance by priority on the basis of the comparison between the error log for a newly detected bad sector and the already registered error logs.

Having described the method that manages error logs in the magnetic disk apparatus 1 according to the embodiment above, the present invention is not limited thereto. A recording apparatus, such as an optical disk apparatus and an opt-magnetic disk apparatus, which detects errors in sectors and manages the sector positions where the errors have been detected on the basis of logs in the same manner, is also included in the present invention.

What is claimed is:

1. A method of controlling a memory device connectable to a host for sending out a command to the memory device, the memory device having a medium capable of storing data and including a plurality of sectors, a head for writing data into and reading data from the medium, and a buffer memory for storing information, the method comprising:
receiving information indicating an error of data read out from a sector by the memory device and storing identification information of the sector where the error has been detected in the buffer memory; and
receiving information indicating an error of data read out from a sector by the host and storing in the buffer memory identification information of the sector where the error has been detected such that in the absence of vacant area in the buffer memory, the identification information is written over into an address where information of sector error detected by the memory device has been stored.

2. The method of claim 1, further comprising providing a priority value to the identification information on the basis of a detecting method.

3. The method of claim 2, wherein the storing stores new identification information into an address of the buffer memory where identification information is stored when a priority value of the new identification information is higher than a priority value of the stored identification information.

4. The method of claim 3, wherein the storing stores new identification information into an address of the buffer memory where identification information having a lowest priority value is stored.

5. The method of claim 3, wherein the storing stores new identification information into an address of the buffer memory where identification information which is oldest is stored.

6. A memory device connectable to a host for sending out a command to the memory device, the memory device having a medium capable of storing data and including a plurality of sectors, and a head for writing data into and reading data from the medium, the memory device comprising;
a buffer memory for storing information; and
a processor for receiving information indicating an error of data read out from a sector by the memory device and storing identification information of the sector where the error has been detected in the buffer memory and receiving information indicating an error of data read out from a sector by the host and storing in the buffer memory identification information of the sector where the error has been detected such that in the absence of vacant area in the buffer memory, the identification information is written over into an address where information of sector error detected by the memory device has been stored.

7. The memory device of claim 6, wherein the processor provides a priority value to the identification information on the basis of a detecting method.

8. The memory device of claim 7, wherein the processor stores new identification information into an address of the buffer memory where identification information is stored when a priority value of the new identification information is higher than a priority value of the stored identification information.

9. The memory device of claim 8, wherein the processor stores new identification information into an address of the buffer memory where identification information having a lowest priority value is stored.

10. The memory device of claim 8, wherein the processor stores new identification information into an address of the buffer memory where identification information which is oldest is stored.
